(19) United States
(12) Patent Application Publication
(10) Pub. No.: US 2016/0278216 A1
(43) Pub. Date: Sep. 22, 2016

(54) CURABLE INK AND A METHOD FOR PRINTING AND CURING THE CURABLE INK

(71) Applicant: CAMTEK LTD., Migdal Haemek (IL)

(72) Inventors: Muhammad Iraqi, Tira (IL); Einat Cohen, Givatayim (IL); Eva Igner, Haifa (IL)

(21) Appl. No.: 15/134,516

(22) Filed: Apr. 21, 2016

Related U.S. Application Data
(63) Continuation of application No. 13/594,907, filed on Aug. 27, 2012.

(51) Int. Cl. H05K 3/22; C09D 11/30

(52) U.S. Cl. CPC H05K 3/227; C09D 11/30; B41J 2/01

(57) ABSTRACT

A method for printing onto a printed circuit board comprising: ink jet printing a curable ink onto said printed circuit board, ultraviolet curing of the curable ink; and curing the curable ink with thermal energy; wherein the curable ink comprises a mixture of reactive monomers and oligomers; at least one pigment; at least one photo initiator; and at least one resin out of phenolic resin, amino resin and epoxy resin.

### CROSS REFERENCE TO RELATED APPLICATIONS

This application is a continuation of U.S. patent application Ser. No. 13/594,907 filing date Aug. 27, 2012 that is incorporated herein by reference.

### BACKGROUND OF THE INVENTION

Printed circuit boards (PCBs) serve to interface and connect the various components in electronic devices. The production of a PCB is a multi-step process that includes coating the PCB with solder mask (SM) ink to form a protection layer for the areas, and conductors that are later not intended to be used for component soldering, marking the PCB with a legend showing the location of each part on the board, the identification number, and the polarity of the part, together with other possibly necessary markings. Conventionally, the formation of the solder mask may include coating the entire PCB with the SM ink and exposing the SM ink to light according to a desired pattern either directly with a laser printer or indirectly by shining light through a prepared artwork film. In one instance, the unexposed area of the SM ink is washed away, and the remaining SM ink is finally cured. In another instance, the exposed area is washed away and the remaining SM ink is further cured. In either case, inaccurate alignment, multiple handling, the need to manufacture accurate artworks result in costly, inefficient, and where PCBs have very small features impossible to manufacture.

Inkjet application of SM circumvents all of the above problems and enables efficient manufacturing with low cost and high yield. Using inkjet, direct deposition of the SM is made only where it is needed, and after automatic alignment of the print heads and computer provided images with the acquired images of copper features on the PCB using digital means.

Materials that can be used for legend printing and that can be deposited using inkjet methods are described in PCT patent application PCT/IL01/0116, publication serial number WO00246323A2 of Zohar et al., Titled “UV CURABLE INK-JET LEGEND INK FOR PRINTING ON PRINTED CIRCUIT BOARD”.

Said materials are not capable of performing the tasks expected of solder mask as they are not capable of withstanding some of the aggressive processes that may be applied during and/or after solder mask deposition and curing. An example of such an aggressive process is electroless nickel immersion gold (ENIG) coating applied on copper pads that are not covered by solder mask. This process improves solderability and protects the pads.

If ENIG is applied on a PCB that is coated with solder mask prepared according to the compositions and methods described in WO00246323A2 will cause the destruction of the said solder mask coating.

### SUMMARY OF THE INVENTION

There is provided a curable ink for printing on a printed circuit board that may include: a mixture of reactive monomers and oligomers; at least one pigment; at least one photo initiator; and at least one resin out of phenolic resin, amino resin and epoxy resin.

The ink may be used for printing a solder mask.

The ink may be formulated so that it has a high viscosity of about 40-200 cp at 25.degree. C., and a low viscosity of about 10-20 cp at a high temperatures of about 30-90.degree. C., and wherein the image cured with UV and by thermal means can withstand dipping in a solder bath at 260.degree. C. or ENIG without substantial degradation

The at least one resin may include a phenolic resin.

The phenolic resin may be phenol aldehyde condensates that include hydrogenated grades.

The phenolic resin may be homopolymers and copolymers of alkenyl phenols including hydrogenated grades.

The phenolic resin may be a poly vinyl phenol resin that includes copolymers of vinyl-phenol and styrene or acrylic and methacrylic acid.

The at least one resin may include amino resin.

The amino resin may be one out of melamine monomer, melamine polymer, melamine-formaldehyde resin and urea-formaldehyde resins.

The amino resin may be selected out of a group consisting of benzoguanamine-formaldehyde resin, glycoluril-formaldehyde resin and triazine based amino resins.

The at least one resin may include epoxy resin.

The epoxy resin may be one out of epoxy-phenol novolaks and epoxy-cresol novolaks.

The resins may include two or more resins out of phenolic resin, amino resin and epoxy resin.

The resins may be phenolic resin, amino resin and epoxy resin.

The ink may include over 90% solids.

The pigment may have a particle size of less than 2 micron.

The mixture of reactive oligomers and monomers may be present in an amount from 60 to 90% by weight of the ink.

At least one of the monomers may be an adhesion promoting monomer.

The ink may include a dispersing agent.

The pigment may include one or more metal oxide.

The additive may include functional filler aimed at achieving better hiding power and optical density.

The ink may include at least one wetting agent.

The wetting agent may be present in an amount of about 0.01-5% by weight of the ink.

The at least one additive may be a rehological additive.

According to an embodiment of the invention a method for printing onto a printed circuit board is provided and may include: ink jet printing of a curable ink onto said printed circuit board, ultraviolet curing of the curable ink; and curing the curable ink with thermal energy.

The ink can have any of the compositions listed above or in any other place in the specification.

According to an embodiment of the invention there is provided a curable ink for printing on printed circuit boards using an ink jet printer comprising a trifunctional urethane oligomer 10-30% by weight, a diacrylate monomer 5-15% by weight, an ethoxylated triacrylate monomer 10-20% by weight, an ethoxylated tetraacrylated monomer 5-15% by weight, an amine coinitiator 1-5% by weight, a photoinitiator 1-5% by weight, a titanium dioxide pigment 10-30% by weight, and at least one resin out of phenolic resin, amino resin and epoxy resin.

A method for printing onto a printed circuit board comprising ink jet printing a curable ink as specified above is provided.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates a method according to an embodiment of the invention.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### A Dual Curing Process and Highly Durable Ink Formulation

There is provided an ink that can be used for printing a solder mask. The ink can withstand aggressive manufacturing processes. The formulation of the ink and the dual curing process (thermal and ultraviolet) provide a highly durable ink.

The ink can be jetted from a printer to provide a coating that can be used to selectively coat the PCB with a layer that can among other characteristics may also function as a “solder mask” (SM) sometimes called “solder resist”.

The inventors have surprisingly found that an addition of one or more certain resins to a known formulation (described in WO00246323A2), such as phenolic resins, amino resins or epoxy resins can provide a curable ink that can withstand the various aggressive chemical, thermal and mechanical processes during the PCB manufacturing and assembly processes.

The phenolic resins that can be used in the formulation are selected from (a) phenol aldehyde condensates including hydrogenated grades (b) homopolymers and copolymers of alkenyl phenols including hydrogenated grades (c) poly vinyl phenol resin including copolymers of vinyl-phenol and styrene or acrylic and methacrylic acid.

The Amino resins are selected from melamine monomer or polymer, melamine-formaldehyde resins, urea-formaldehyde resins, benzoguanamine-formaldehyde resins, glycoluril-formaldehyde resins, and triazine based amino resins.

Epoxy resins are selected from epoxy-phenol novolaks and epoxy-cresol novolaks.

According to an embodiment of the invention the curable ink can be UV cured and then cured by heat energy—for example by placing it in an oven at a certain temperature for a certain period. This curable ink after being UV cured and heat cured is capable of withstanding many PCB finishing processes including electroless nickel immersion gold (ENIG) which is well known for its aggressively, and thus can be used as SM as well as other coatings in PCB manufacturing. Various materials, various temperatures and various curing times in the oven provide different adhesion performance.

When the PCB coated with said curable ink is cured with UV during the printing operation and is further cured in an oven at high temperatures (100-200.degree. C.) for a minimum length of time (10-300 min), the coating is now resistant to the aggressive manufacturing processes. Said coating possesses the qualities required of solder mask. The length of time required for oven curing and the oven temperature may depend among others, on the specific composition of the material e.g the thermosetting resins such as phenolic, amine resins.

The curable ink may be applied on the PCB using printing techniques such as but not limited to ink-jet printing.

In one embodiment, one or more ultraviolet (UV) energy sources are positioned relative to the ink jet heads such that the material that is deposited by the ink jet heads is exposed to UV energy which initiates an initial curing of the material. This UV curing enables further safe handling of the PCB but may not be sufficient to withstand the ensuing manufacturing processes. The PCB is then placed in a heated environment such as but not limited to an oven which is preheated to a preset temperature/or temperature profile for a predetermined time. This operation completely cures the coated solder mask material rendering it fully resistant to the ensuing aggressive manufacturing processes.

According to an embodiment of the invention the curable ink may include at least one resin out of phenolic resin, amino resin and epoxy resin and a mixture of oligomers and monomers which have 1 to 5 functional groups (which can undergo cross linking by UV light), and are chosen to so as to optimize film properties after curing, such as hardness, flexibility, resistance to solvents and adhesion.

The monomers serve as reactive diluents enabling a coating which is composed of close to 100% solids. Such monomers and oligomers can be selected from, but not limited to, epoxy acrylates, polyester acrylates, urethane acrylates, etc. . . .

The ink may include components such as, (from Sartomer), 6 hexanediol diacrylate (SR 238), aromatic epoxy acrylate (CN115), amine modified polyetheracrylate oligomers (CN 502), amine modified polyetheracrylate oligomer CN550), acrylated amine (CN 386), aromatic monoacrylate oligomer (CN131), isobornyl acrylate (SR506), Iris (2-hydroxy ethyl) isocyanurate triacrylate (SR368), dipentaerythritol pentaacrylate (SR399), Ethoxylated(4)pentaerythritoltetraacrylate (SR494), Ethoxylated 3Trimethylolpropane Triacrylate (SR 454) and others. The mixture may be further comprised of monomers chosen to promote adhesion such as Tetrahydrofurfuryl acrylate (SR-285) and Tetrahydrofufuryl methacrylate (SR-203).

In addition, since the PCB external layer is composed of a glass-epoxy layer, it is advantagous to use oligomers and monomers which have chemical moieties similar to the solder, such as epoxy groups.

The coating may also include a mixture of photoinitiators designed to lead to a thorough cure of the film, both on the surface and in depth, by the choice of photoinitiators for in depth and surface curing. Photoinitiators that function mainly for surface curing are such as benzophenone with ITX, Bis(2.4.6-trimethylbenzoyl)-phenylphosphineoxide(Irg819), together with Bis(2,6-dimethoxybenzoyl)-2,4,4-trimethyl-pentylphineoxide(Irg1 800), 2-Hydroxy-2methyl-1-phenyl-propan-1-one(Irg 1173), 2,4,6-Trimethylbenzoyl-diphenyl-phosphineoxyde (Darocure4265)7 through curing (such as Irgacure 819, 184), and also photoinitiators which are capable of being crosslinked together with the monomers and oligomers (such as amine acrylate).

A further component of the photoreactive mixture is an amine coinitiator such as ethylene dimethyl amine benzoate (EDB) or an acryl amine. These synergysts serve as oxygen scavengers, sustaining the free radical reaction in the presence of oxygen. In addition, alkoxylated monomers and oligomers serve as efficient oxygen scavengers.

Another way to overcome the problem of oxygen scavenging, obvious to those well versed in the art of radiation cured films, is to use a cationic curing mechanism.

Examples of coinitiators for the cationic initiated cross linking are: triaryl sulphonium hexafluorophosphate CD1011, and diaryl iodonium hexafluoroantimonate (CD1012).

The pigment in the ink consists of organic or inorganic particles, depending on the required color. For example, white legend ink can be formulated with fine titanium oxide particles, as Kronos 2300, Kemira 65O, Tioxide TR92, Kemira L181, to mention just a few. Concentration of the pigment can vary, according to the required final optical density, or hiding power, and is typically between 10-35% wt.

The particle size of the pigments should be below 2 um (micron), and more preferably below 0.9 um. It should be noted that the inclusion of the titania pigments in the ink present the problem of light reflection by the pigment particles, which may interfere with the curing process. For this reason, the photoinitiators and the pigments are carefully selected to allow proper curing and adhesion of the ink to the PCB.

In order to obtain a good dispersion of the pigment particles, dispersing agents such as Disperbyk 110, which is a copolymer with acidic groups, Disperbyk 168 which is a high molecular weight block copolymer with pigment affinic amine groups (from Byk Chemie), EFKA 1800, Texaphor 963, which is a polycarboxylic acid with amine derivatives (from Henkel) and others, may be used. More preferably, dispersion agents which are capable of participating in the cross linking reaction, such as LPN 7057, which is high molecular weight block copolymer in oligotriacrylate (from Byk Chemie), may be included in the formulation.

The ink may also contain wetting agents, such as Byk 333, Byk 307 which are polyether modified polydimethyl polysiloxane (from Byk Chemie), which help in obtaining smooth surfaces, and prevent surface problems such as dewetting, “fish eyes” etc. To improve the quality of printed lines additives such as BYK 358, BYK 354 (polyacrylates from Byk Chemie), or other higher molecular weight additives may be added to improve adjacent drops coalescence, without decreasing surface tension.

### EXAMPLES

The examples provided are for the purposes of clarification and example only.

They are in no way intended to limit the scope of the invention, as set out in the claims.

### Example 1

Polyester/polyether based trifunctional urethane blended with hexandiol diacrylate (CN945B85).sup.1 20% (percent by weight of the total ink).sup.1, 6 Hexandiol Diacrylate 15% (SR238).sup.1 Ethoxylated(4) pentaerythritol tetraacrylate 19% (SR 494).sup.1 Tetrahydrofurfuryl Acrylate 10% (SR285).sup.1 Ethoxylated3 Trimethylolpropane Triacrylate 9.5% (SR 454).sup.1 Difunctional amine coinitiator (CN3861).sup.1 2% Bis(2,4,6-trimethylbenzoyl)-phenylphosphineoxide (Irgacure 819).sup.2, 1% 2-hydroxy-2-methyl-1-phenyl-propan-1-one (Darocurl 173).sup.2 2% Titanium dioxide 20% High weight molecular block copolymer with pigment affinic groups in olygotriacrylate diluent 1% (Byk-Lp N 7057).sup.3, 1% Polyether modified poly-dimethyl-polysiloxane (Byk 333).sup.3 0.5% and at least one resin out of phenolic resin, amino resin and epoxy resin.

Wherein .sup.1 represents a material manufactured by Sartomer (Cray Valley), .sup.2 represents materials manufactured by Ciba-Giegy, and .sup.3 represents materials manufactured by Byk Chemie.

The above ink provided good results after being jetted from an ink jet printer and cured at 700 mj/cm2. The viscosity of the ink was 140 cp at 25.degree. C. and 18 cp at 75.degree. C. (jetting temperature).

### Example 2

Polyester/polyether based trifunctional urethane blended with hexandiol diacrylate (CN945B85) 20%, 1.6 Hexandiol Diacrylate 15% Ethoxylated (4) pentaerythritol tetraacrylate 19% Tetrahydrofurfuryl Acrylate 10% Ethoxylated (3) Trimethylolpropane Triacrylate 9.5% Difunctional amine coinitiator (CN386) 2% 1-hydroxycyclohexyl phenyl ketone (Irgacure 184) 4% Ethyl-4-dimethylaminobenzoate (EDB) 3% Fumed silica 1% Polyether modified poly-dimethyl-polysiloxane (Byk 333) 0.5% Mofied polyacrylate with pigment affinic groups in triethylene glycol divinylether (Efka-4800) 1% Titanium dioxide 15% and at least one resin out of phenolic resin, amino resin and epoxy resin.

Still further the present invention relates to a method for printing onto a printed circuit board comprising ink jet printing the heat curable ink described above onto a printed circuit board.

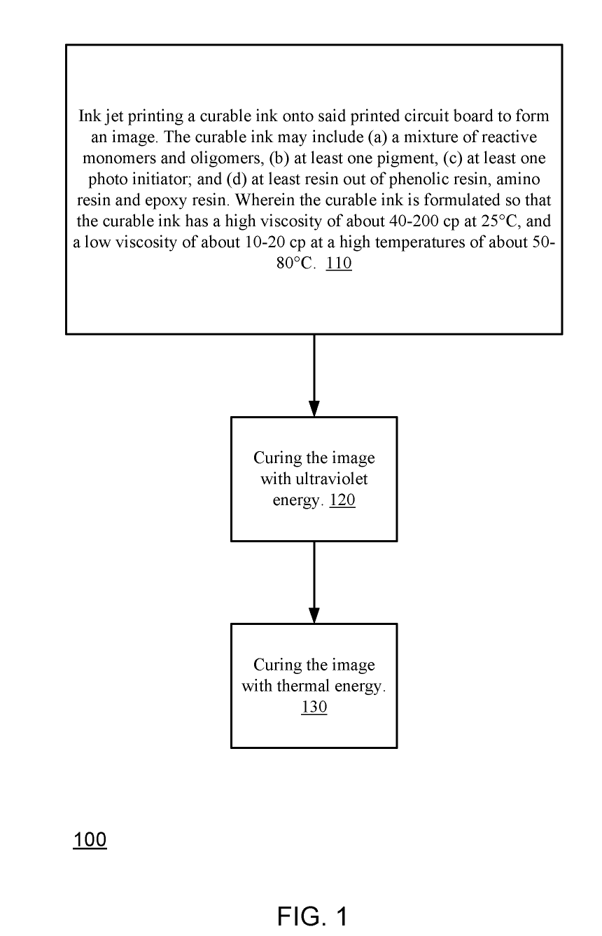

FIG. 1 illustrates method 100 according to an embodiment of the invention.

Method 100 for printing onto a printed circuit board may start by stage 110 of ink jet printing a curable ink onto said printed circuit board to form an image. The curable ink may include a mixture of reactive monomers and oligomers; at least one pigment; at least one photo initiator; and at least resin out of phenolic resin, amino resin and epoxy resin. Wherein the curable ink is formulated so that the curable ink has a high viscosity of about 40-200 cp at 25.degree. C., and a low viscosity of about 10-20 cp at a high temperatures of about 50-80.degree. C.

Stage 110 may be followed by stage 120 of curing the image with ultraviolet energy.

Stage 120 may be followed by stage 130 of curing the image with thermal energy.

Wherein the image formed by stages 110-130 can withstand a solder deposition at 260.degree. C. or ENIG, immersion tin, immersion silver or any other finish without substantial degradation.

In the foregoing specification, the invention has been described with reference to specific examples of embodiments of the invention. It will, however, be evident that various modifications and changes may be made therein without departing from the broader spirit and scope of the invention as set forth in the appended claims.

We claim:

1. A method for printing onto a printed circuit board comprising: ink jet printing a curable ink onto said printed circuit board, ultraviolet curing of the curable ink; and curing the curable ink with thermal energy; wherein the curable ink comprises a mixture of reactive monomers and oligomers; at least one pigment; at least one photo initiator; and at least one resin out of phenolic resin, amino resin and epoxy resin.

2. The method according to claim 1 wherein the at least one resin comprises phenolic resin.

3. The method according to claim 2, wherein the phenolic resin is phenol aldehyde condensates that includes hydrogenated grades.

4. The method according to claim 2, wherein the phenolic resin is homopolymers and copolymers of alkenyl phenols including hydrogenated grades.

5. The method according to claim 2, wherein the phenolic resin is poly vinyl phenol resin including copolymers of vinyl-phenol and styrene or acrylic and methacrylic acid.

6. The method according to claim 1 wherein the at least one resin comprises amino resin.

7. The method according to claim 6, wherein the amino resin is selected out of a group consisting of melamine monomer, melamine polymer, melamine-formaldehyde resin and urea-formaldehyde resins.

8. The method according to claim 6, wherein the amino resin is selected out of a group consisting of benzoguanamine-formaldehyde resin, glycoluril-formaldehyde resin and triazine based amino resins.

9. The method according to claim 1 wherein the at least one resin comprises epoxy resin.

10. The method according to claim 9, wherein the epoxy resin is selected out of a group consisting of epoxy-phenol novolaks and epoxy-cresol novolaks.

11. The method according to claim 1, wherein the resins comprise two or more resins out of phenolic resin, amino resin and epoxy resin.

12. The method according to claim 1, wherein the resins comprise phenolic resin, amino resin and epoxy resin.

13. The method according to claim 1, wherein the ink contains over 90% solids.

14. The method according to claim 1, wherein the pigment has a particle size of less than 2 micron.

15. The method according to claim 1 wherein the mixture of reactive oligomers and monomers is present in an amount from 60 to 90% by weight of the ink.

16. The method according to claim 16, wherein at least one of the monomers is an adhesion promoting monomer.

17. The method according to claim 1, wherein the ink includes a dispersing agent.

18. The method according to claim 1, wherein the pigment comprises one or more metal oxide.

19. The method according to claim 1, wherein the additive comprises a functional filler aimed at achieving better hiding power and optical density.

20. The method according to claim 1, further comprising at least one wetting agent.

21. The method according to claim 21, wherein the wetting agent is present in an amount of about 0.01-5% by weight of the ink.

22. The method according to claim 1, wherein said at least one additive is a rehological additive.

23. The method according to claim 1, wherein the curable ink comprises a trifunctional urethane oligomer 10-30% by weight, a diacrylate monomer 5-15% by weight, an ethoxylated triacrylate monomer 10-20% by weight, an ethoxylated tetraacrylated monomer 5-15% by weight, an amine coinitiator 1-5% by weight, a photoinitiator 1-5% by weight, a titanium dioxide pigment 10-30% by weight, and at least one resin out of phenolic resin, amino resin and epoxy resin.

24. The method according to claim 1, wherein the curable ink comprises comprising: a mixture of reactive monomers and oligomers; at least one pigment; at least one photo initiator; and at least one resin out of phenolic resin, amino resin and epoxy; wherein the mixture of reactive monomers and oligomers; at least one pigment; at least one photo initiator comprise: Polyester/polyether based trifunctional urethane blended with hexandiol diacrylate; Hexandiol Diacrylate; Ethoxylated pentaerythritol tetraacrylate; Tetrahydrofurfuryl Acrylate; Ethoxylated Trimethylolpropane Triacrylate; Difunctional amine coinitiator; 1-hydroxycyclohexyl phenyl ketone; Ethyl-4-dimethylaminobenzoate; Fumed silica; Polyether modified poly-dimethyl-polysiloxane; Mofied polyacrylate with pigment affinic groups in triethylene glycol divinylether; and Titanium dioxide

25. The method according to claim 1, wherein the curable ink comprises a mixture of reactive monomers and oligomers; at least one pigment; at least one photo initiator; and at least one resin out of phenolic resin, amino resin and epoxy; wherein the mixture of reactive monomers and oligomers; at least one pigment; at least one photo initiator comprise at least one of the following: Polyester/polyether based trifunctional urethane blended with hexanediol diacrylate; Hexanediol Diacrylate; Ethoxylated pentaerythritol tetraacrylate; Tetrahydrofurfuryl Acrylate; Ethoxylated Trimethylolpropane Triacrylate; Amine; Bis(2,4,6-trimethylbenzoyl)-phenylphosphineoxide; 2-hydroxy-2-methyl-1-phenyl-propan-1-one; Titanium dioxide; Copper Phthalocyanine; High weight molecular block copolymer with pigment affinic groups in olygotriacrylate diluent; and Polyether modified poly-dimethyl-polysiloxane.
